(19) United States
(12) Patent Application Publication
(10) Pub. No.: US 2015/0221625 A1
(43) Pub. Date: Aug. 6, 2015

(54) SEMICONDUCTOR PACKAGE HAVING A DISSIPATING PLATE

(71) Applicants: HYUN-SUK CHUN, YONGIN-SI (KR); MIN KIM, HANAM-SI (KR)

(72) Inventors: HYUN-SUK CHUN, YONGIN-SI (KR); MIN KIM, HANAM-SI (KR)

(21) Appl. No.: 14/510,571

(22) Filed: Oct. 9, 2014

(30) Foreign Application Priority Data
Feb. 4, 2014 (KR) 10-2014-0012670

(51) Int. Cl. H01L 25/18; H05K 7/20; H01L 25/065; H01L 23/31; H01L 23/367; H01L 23/00; H05K 7/02; H01L 23/12

(52) U.S. Cl. CPC H01L 25/18; H05K 7/023; H05K 7/20409; H01L 23/12; H01L 23/3107; H01L 23/3675; H01L 24/17; H01L 24/32; H01L 25/0657; H01L 2924/1431; H01L 2924/1434; H01L 2224/16113; H01L 2224/16227; H01L 2224/16057; H01L 2224/32245; H01L 2225/06513; H01L 2225/06517; H01L 2225/06541; H01L 2225/06589; H01L 2225/06586

(57) ABSTRACT

A semiconductor package includes an integrated circuit device on a circuit board, a mold layer covering the integrated circuit board, a dissipating plate that dissipates heat from the integrated circuit device and a thermal conductive adhesive having a thermal interface material (TIM). The dissipating plate includes at least one protrusion protruding from a peripheral portion of the bottom of the dissipating plate that is inserted into the mold layer around the integrated circuit device. The dissipating plate is primarily secured to the mold layer by the protrusion, not by the thermal conductive adhesive. The thermal conductive adhesive includes a low modulus TIM (LMTIM) that supplementally adheres the dissipating plate to the mold layer.

### CROSS-REFERENCE TO RELATED APPLICATIONS

This application claims priority under 35 U.S.C §119 from Korean Patent Application No. 10-2014-0012670 filed on Feb. 4, 2014 in the Korean Intellectual Property Office, and all the benefits accruing therefrom, the contents of which are herein incorporated by reference in their entirety.

### BACKGROUND

1. Field

Exemplary embodiments are directed to a semiconductor package, and more particularly, to a semiconductor package having a dissipating plate such as a heat slug.

2. Description of the Related Art

As recent electronic devices have been more highly integrated with improved performance, semiconductor packages are also manufactured to be smaller denser. Higher performance from high density semiconductor packages at higher speeds necessarily generates more heat in the semiconductor package. Thus, sufficient thermal dissipation becomes a useful factor for increasing the operation stability and product reliability of a semiconductor package and of electronic systems that include a semiconductor package. For those reasons, various dissipation systems have been suggested for high density semiconductor packages.

Thermal interface materials (TIM) may be used in dissipating systems according to the structures of the semiconductor package. For example, a TIM may be used for heat transfer between a lower chip and an upper circuit board to which an upper chip is mounted in a stacked package such as a package-on-package (PoP) having a configuration in which the upper circuit board is combined by a solder ball with a lower circuit board having the lower chip. In contrast, a TIM may also be used for both heat transfer and adhesion between a chip and a dissipating plate, such as a heat slug adhered to a top surface of a single chip package. For those reasons, a low modulus TIM (LMTIM) is mainly used for most stacked packages, while a high modulus TIM (HMTIM) is mainly used for single chip packages.

However, HMTIM may cause cracks on a single chip package due to the high modulus thereof. Various scratches and dents may be generated on the top surface of a single chip package in a packaging process and the scratches and dents are usually formed into the cracks in a subsequent process due to the high modulus of the HMTIM.

### SUMMARY

Embodiments of the present inventive concept may provide a semiconductor package having a dissipating plate on which a fixing protrusion is provided.

According to an aspect of the present inventive concepts, there is provided a semiconductor package that includes a mold layer securing an integrated circuit device to a circuit board and that encapsulates the integrated circuit device from its surroundings so that the integrated circuit device may be coplanar with an upper surface of the mold layer and an upper surface of the integrated circuit device may be exposed through the mold layer, a dissipating plate disposed on the integrated circuit device and the mold layer that dissipates heat from the integrated circuit device, and a dissipating adhesive that adheres the dissipating plate to the mold layer and the integrated circuit device therebetween. The dissipating plate may include at least one protrusion that may protrude from a peripheral portion of a bottom thereof and may penetrate into the mold layer. The dissipating adhesive may transfer heat from the integrated circuit device to the dissipating plate.

In some embodiments, the mold layer may fill a gap space between the circuit board and the integrated circuit device and side spaces adjacent to the integrated circuit device.

In some embodiments, the mold layer may include an under-fill mold in a gap space between the integrated circuit device and the circuit board and an encapsulant that fills side spaces adjacent to the integrated circuit device.

In some embodiments, the dissipating plate may make contact with the upper surface of the mold layer and the upper surface of the integrated circuit device, and the mold layer may include at least one recess in the upper surface thereof that corresponds to the protrusion of the dissipating plate.

In some embodiments, the protrusion and the recess may be continuous along the peripheral portion of the bottom of the dissipating plate, so that the protrusion may have a ring shape that encloses the integrated circuit device in the mold layer.

In some embodiments, the protrusion and the recess may be discontinuous along the peripheral portion of the bottom of the dissipation plate, so that the protrusion may include a plurality of protrusion pieces symmetric with each other with respect to the integrated circuit device.

In some embodiments, the semiconductor package may further include an additional adhesive between the protrusion and an inner surface of the recess.

In some embodiments, the dissipating adhesive may include a penetration hole through which the protrusion penetrates and may comprise a low modulus thermal interface material (LMTIM).

In some embodiments, the semiconductor package may further include an additional circuit board under the circuit board, an additional integrated circuit device on the additional circuit board, and at least one inter-board connector that connects the circuit board and the additional circuit board. Thus, the semiconductor package may have a package-on-package (PoP) structure.

In some embodiments, the additional integrated circuit device may include a logic chip and the integrated circuit device includes a plurality of stacked memory chips.

In some embodiments, the integrated circuit device and the additional integrated circuit device may include a flip chip structure and the stacked memory chips are connected with each other by a plurality of inter-chip connectors.

In some embodiments, the integrated circuit device and the additional integrated circuit device may include a plurality of stacked memory chips.

According to an aspect of the present inventive concepts, there is provided a semiconductor package that includes a mold layer that secures an integrated circuit device to a circuit board, encapsulates the integrated circuit device from its surroundings; a dissipating plate disposed on an upper surface of the integrated circuit device and an upper surface of the mold layer that is configured to dissipate heat from the integrated circuit device, and a dissipating adhesive between the dissipating plate and the mold layer and the integrated circuit device and comprises a low modulus thermal interface material (LMTIM) that is configured to transfer heat from the integrated circuit device to the dissipating plate. The mold layer includes at least one recess in a peripheral portion of an upper surface thereof, the dissipating plate including at least one protrusion that protrudes from a peripheral portion of a bottom thereof and penetrates into the recess of the mold layer to combine with the mold layer with an interference fit, and the dissipating adhesive includes a penetration hole through which the protrusion penetrates.

In same embodiments, an upper surface of the integrated circuit device may be coplanar with an upper surface of the mold layer, and an upper surface of the integrated circuit device may be exposed through the mold layer. The mold layer may fill a gap space between the circuit board and the integrated circuit device and side spaces adjacent to the integrated circuit device.

In some embodiments, an upper surface of the integrated circuit device may be coplanar with an upper surface of the mold layer, and the mold layer may include an under-fill mold in a gap space between the integrated circuit device and the circuit board and an encapsulant that fills side spaces adjacent to the integrated circuit device. An upper surface of the integrated circuit device may be exposed through the encapsulant.

In some embodiments, the protrusion and the recess may be continuous along the peripheral portion of the bottom of the dissipating plate, and the protrusion may have a ring shape that encloses the integrated circuit device in the mold layer.

In some embodiments, the protrusion and the recess may be discontinuous along the peripheral portion of the bottom of the dissipation plate, and the protrusion may include a plurality of protrusion pieces that are symmetric with each other with respect to the integrated circuit device.

In some embodiments, the semiconductor package may further include an additional adhesive between the protrusion and an inner surface of the recess.

In some embodiments, the semiconductor package may further include an additional circuit board under the circuit board, an additional integrated circuit device on the additional circuit board, and at least one inter-board connector that connects the circuit board and the additional circuit board. The semiconductor package may have a package-on-package (PoP) structure.

In some embodiments, the integrated circuit device may include a plurality of stacked memory chips, the integrated circuit device and the additional integrated circuit device may include a flip chip structure, and the stacked memory chips may be connected with each other by a plurality of inter-chip connectors.

According to exemplary embodiments of the present inventive concepts, heat from a heat source of the semiconductor package may dissipate outwards through the dissipating plate and the dissipating plate may be stably secured to the mold layer of the semiconductor package. Therefore, a thermal conductive adhesive interposed between the mold layer and the dissipating plate may be supplementary for securing the dissipating plate and thus the thermal conductive adhesive may include a low modulus TIM (LMTIM) as a dissipating agent in place of a high modulus TIM (HMTIM).

Thus, an LMTIM instead of an HMTIM may be used for manufacturing the semiconductor package irrespective of a single package and a stack package, which may standardize the packaging process for manufacturing a semiconductor package. In addition, the dissipating efficiency of a single chip package may be increased by replacing a conventional HMTIM with an LMTIM.

### BRIEF DESCRIPTION OF THE DRAWINGS

FIG. 1 is a structural view of a semiconductor package in accordance with an exemplary embodiment of the present inventive concept.

FIGS. 2A to 2C are plan views of fixing protrusions of the dissipating plate in the semiconductor package shown in FIG. 1.

FIG. 3 is an enlarged view of a portion ‘A’ of the semiconductor package shown in FIG. 1.

FIG. 4 is structural view of a modification of the semiconductor package shown in FIG. 1.

FIG. 5 is a structural view of a stack semiconductor package in accordance with another exemplary embodiment of the present inventive concept.

FIG. 6 is a structural view of a modified package of the semiconductor stack package shown in FIG. 5.

### DETAILED DESCRIPTION OF EXEMPLARY EMBODIMENTS

Various exemplary embodiments will be described more fully hereinafter with reference to the accompanying drawings, in which some exemplary embodiments are shown. The present invention may, however, be embodied in many different forms and should not be construed as limited to the exemplary embodiments set forth herein. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. Like numerals may refer to like elements throughout.

Hereinafter, exemplary embodiments will be explained in detail with reference to the accompanying drawings.

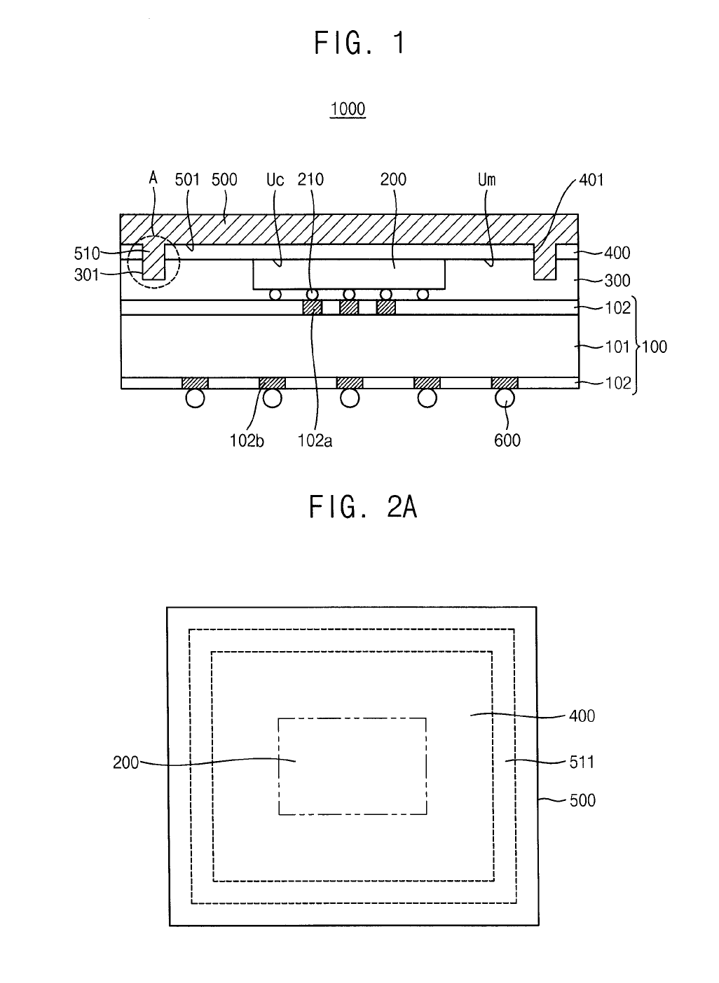

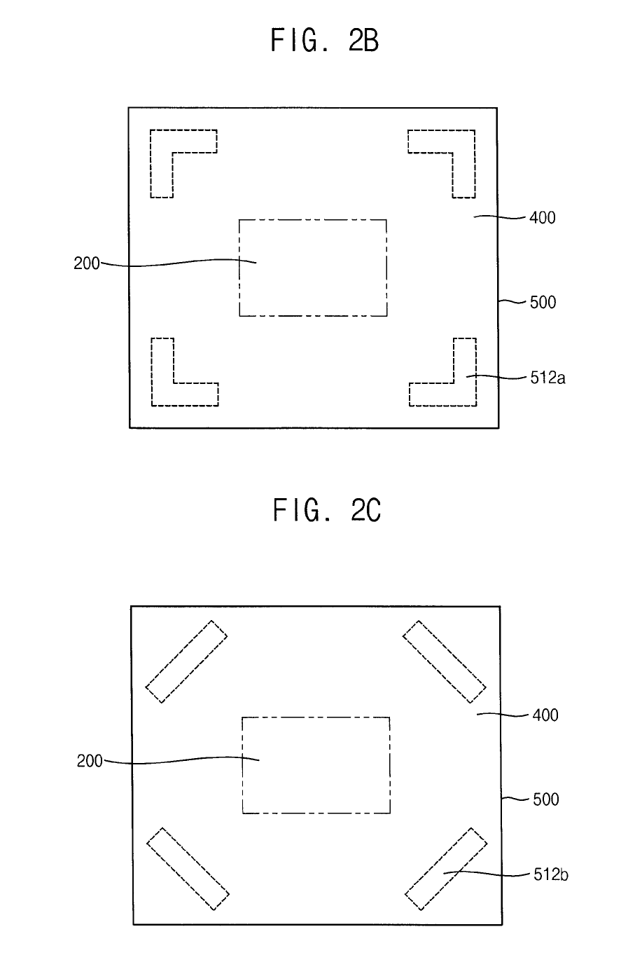

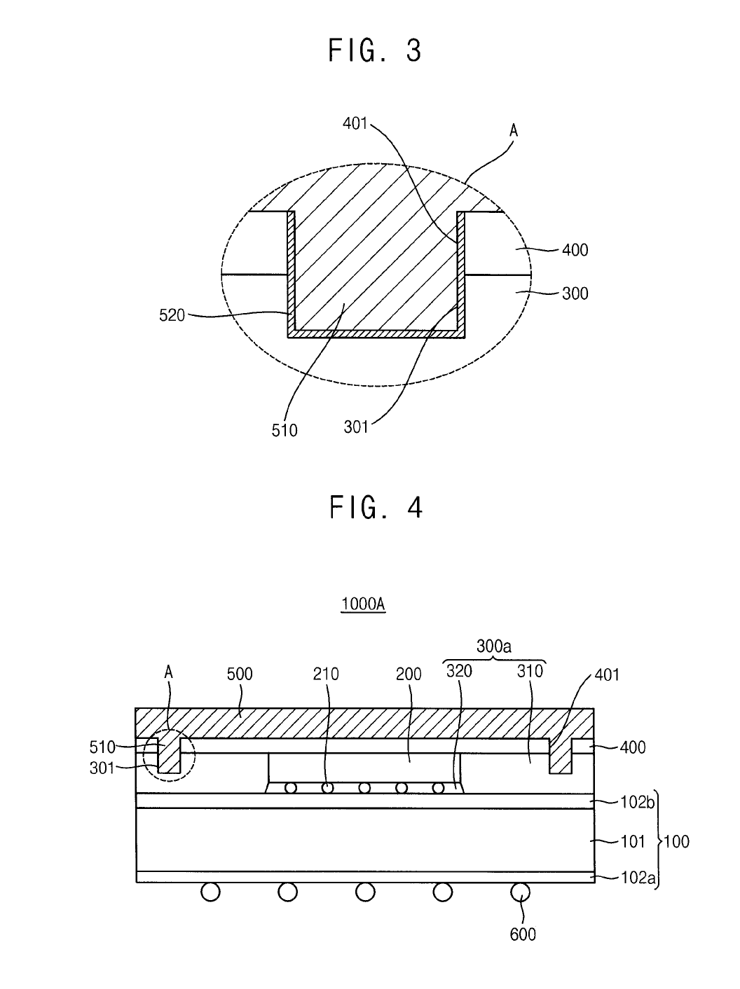

FIG. 1 is a structural view of a semiconductor package in accordance with an exemplary embodiment of the present inventive concept. FIGS. 2A to 2C are plan views of fixing protrusions of the dissipating plate in the semiconductor package shown in FIG. 1. FIG. 3 is an enlarged view of a portion ‘A’ of the semiconductor package shown in FIG. 1. FIG. 4 is structural view of a modification of the semiconductor package shown in FIG. 1.

Referring to FIGS. 1 to 4, a semiconductor package 1000 in accordance with an exemplary embodiment of the present inventive concept may include a circuit board 100 that has an electronic circuit pattern therein, at least one integrated circuit device 200 on the circuit board 100, a mold layer 300 that secures the integrated circuit device 200 to the circuit board 100 and encapsulates the integrated circuit device 200 from its surroundings so that the integrated circuit device 200 is coplanar with an upper surface Um of the mold layer 300 and an upper surface Uc of the integrated circuit device is exposed through the mold layer 300, a dissipating plate 500 on the integrated circuit device 200 and the mold layer 300 that dissipates heat from the integrated circuit device 200, and a thermal conductive adhesive 400 that adheres the dissipating plate 500 to the mold layer 300 and the integrated circuit device 200 therebetween. The dissipating plate 500 may have at least one protrusion 510 that may protrude from a peripheral portion of a bottom 501 and penetrate into the mold layer 300. The thermal conductive adhesive 4000 may transfer heat from the integrated circuit device 200 to the dissipating plate 500.

In an exemplary embodiment, the circuit board 100 may include a board body 101 that may be a rigid plate that comprises insulating and heat-resistive materials. Circuit patterns may be disposed inside the board body 101 and may be insulated from each other by an insulation layer 102. The circuit patterns may be connected to their surroundings via upper contact pads 102a and lower contact pads 102b.

The board body 101 of the circuit board 100 may include a thermosetting plastic plate such as an epoxy resin plate or a polyimide plate. Alternatively, the board body 101 may include a plate on which a heat-resistive organic film such as a liquid crystal polyester film or a polyamide film may be coated. The circuit patterns may include a plurality of conductive lines or wirings arranged in the board body 101, and may include a power line for applying electric power, a plurality of signal lines for communicating data signals with the integrated circuit chip 200 and a ground line for electrically grounding the signal lines and the power line. The conductive lines or wirings of the circuit patterns may be electrically insulated from each other by the insulation layer 102.

The circuit patterns may be connected to a plurality of upper and lower contact pads 102a and 102b that may be arranged on upper and lower faces of the board body 101. Surrounding devices may be electrically connected to the circuit patterns via the contact pads 102a and 102b. In a present exemplary embodiment, the integrated circuit device 200 may be electrically connected to the circuit patterns via the upper contact pads 102a and a plurality of contact terminals 600 may be arranged on the lower contact pads 102b at a bottom of the circuit board 100 and an external device may make contact with the contact terminals 600. The semiconductor package 1000 may make contact with a system board of an electronic system via the contact terminals 600. For example, the contact terminals 600 may include solder balls.

The circuit board 100 may include a printed circuit board (PCB) in which the circuit patterns may be formed by a printing process. In particular, the circuit board 100 may include a PCB for a molded under-fill (MUF) process (hereinafter, referred to as MUF PCB) in which an under-fill process that fills a gap space between the integrated circuit device 200 and the circuit board 100 and an encapsulating process that encloses the integrated circuit device 200 on the circuit board 100 may be simultaneously performed in a single process.

The integrated circuit device 200 may include an active device on the circuit board 100. Thus, when electric power is applied to the integrated circuit device 200, an electric operation such as electric amplification and electric oscillation may be conducted which may, as a result, generate driving heat from the integrated circuit device 200.

For example, the integrated circuit device 200 may include a plurality of conductive structures stacked on a semiconductor substrate such as a silicon wafer using a plurality of insulation interlayers, and a plurality of wiring structures separated from the conductive structures by the insulation interlayers that transfer signals to the conductive structures. The conductive structures and the wiring structures may be protected from their surroundings by a passivation layer.

The conductive structures may include, for example, a unit structure of a dynamic random access memory (DRAM) device that has a transistor and a capacitor that correspond to each other. In some embodiments, the conductive structures may include, for example, a unit transistor of an operation block of a flash memory device that includes string transistors, cell transistors and ground transistors. The conductive structures may include, for example, at least one logic device for operating a DRAM device or a flash memory device.

The wiring structure may include a metal plug that penetrates through the insulation interlayer and makes contact with the conductive structure and a metal wiring on the insulation interlayer. The metal wiring may include a signal line for transferring input/output signals to the conductive structure, a power line for applying electric power to the conductive structure, and a ground line for electrically grounding the conductive structure.

The integrated circuit device 200 may include, for example, a flip chip structure in which an active face of the integrated circuit device 200 may face down toward an upper surface of the circuit board 100. Thus, interconnectors 210 such as, for example, solder bumps, may be interposed between electrode pads of the integrated circuit device 200 and the contact pads 102a of the circuit board 100. Thus, the integrated circuit device 200 may be electrically connected to the circuit board 100 via the interconnectors 210. The interconnectors 210 may be bonded to the circuit board 100 by a heat treatment such as a reflow process and the gap space between the integrated circuit device 200 and the upper surface of the circuit board 100 may be filled by the mold layer 300.

In a present exemplary embodiment, the mold layer 300 may be formed through an MUF process in which the gap space between the integrated circuit device 200 and the circuit board 100 together with side spaces between neighboring integrated circuit devices 200 on the circuit board 100 may be filled with the mold layer 300. That is, the gap space under the integrated circuit device 200 and side spaces adjacent to the integrated circuit device 200 may be filled with the mold layer 300 in a single process. The mold layer 300 may include an exposed under-fill mold layer by which the upper surface Uc of the integrated circuit device 200 may be exposed. Alternatively, as shown in FIG. 4, the gap space under the integrated circuit device 200 may be filled with an under-fill mold 320 and the side space between and adjacent to the neighboring integrated circuit devices 200 may be filled with an encapsulant 310. According to a modification 1000A of the semiconductor package 1000 shown in FIG. 1, the integrated circuit device 200 may be molded by a modified mold layer 300a that includes the under-fill mold 320 and the encapsulant 310, to improve the bonding reliability of the integrated circuit device 200 to the circuit board 100.

In addition, the integrated circuit device 200 may be mounted on the circuit board 100 so that the active face may face upwards, and thus the integrated circuit device 200 may be bonded to the circuit board 100 by a bonding wire.

The integrated circuit device 200 may be, for example, a single chip structure and/or a multichip structure such as a chip stack package in which a plurality of chips may be stacked. A single chip structure may include a memory device, such as a dynamic random access memory (DRAM) device or a flash memory device, and a logic device for driving the memory device. A single chip structure may include, for example, a chip scaled package (CSP) that has a single semiconductor chip such as a wafer level chip scaled package (WLCSP). A WLCSP may include a plurality of semiconductor chips and solder bumps bonded on a single wafer, and the assembly of the semiconductor chips and the solder bumps may be separated into pieces by a unit of the semiconductor chip or a die. A WLCSP may be mounted on the circuit board 100 in a flip chip structure. A multichip structure may include a memory package in which a plurality of memory chips may be stacked and memory chips are connected to each other by inter-chip connectors. In particular, each chip of a multichip structure may be electrically connected with each other by various connecting members, such as penetration electrodes and bonding wires.

The mold layer 300 may secure the integrated circuit device 200 to the circuit board 100 and may protect the integrated circuit device 200 from external surroundings. The mold layer 300 may include a rigid insulating resin, such as an epoxy molding compound (EMC) that may be disposed on a whole surface of the circuit board 100.

The mold layer 300 may be formed on the circuit board 100 by a single MUF process in which the gap space under the integrated circuit device 200 and the side space adjacent to the integrated circuit device 200 may be simultaneously filled up with mold materials. Alternatively, the mold layer 300 may be formed on the circuit board 100 by sequentially performing an under-fill process to fill the gap space under the integrated circuit device 200 and an encapsulating process to fill in the side spaces between the neighboring integrated circuit devices 200.

In particular, the upper surface Um of the mold layer 300 may be coplanar with the upper surface Uc of the integrated circuit device 200, so that the upper surface Uc of the integrated circuit device 200 may be exposed to its surroundings through the mold layer 300. Therefore, heat may be efficiently dissipated from the integrated circuit device 200.

When forming the mold layer 300 by an MUF process, the integrated circuit device 200 and circuit board 100 assembly may be installed into a mold case so that the upper surface Uc of the integrated circuit device 200 makes contact with a top surface of the mold case, after which an epoxy mold compound (EMC) may be supplied into the mold case under a set temperature and pressure. Thus, a liquefied epoxy mold compound may flow into void spaces between the circuit board 100 and the integrated circuit device 200 in the mold case, to simultaneously fill the void spaces, including the gap space under the integrated circuit device 200 and the side spaces between the neighboring integrated circuit devices 200, with the liquefied epoxy mold compound. Therefore, the integrated circuit device 200 may be encapsulated from its surroundings by the mold layer 300 such that the upper surface Uc of the integrated circuit device 200 may be coplanar with the upper surface Um of the mold layer 300 and may be exposed through the mold layer 300.

In contrast, when forming the mold layer 300a shown in FIG. 4 by a two-step process, the encapsulant 310 may be formed on the circuit board to a thickness sufficient to cover the integrated circuit device 200 and then the encapsulant 310 may be planarized to expose the top surface Uc of the integrated circuit device 200, so that the upper surface Uc of the integrated circuit device 200 may be coplanar with the upper surface Um of the mold layer 300.

In particular, when the integrated circuit device 200 is mounted onto the circuit board 100 in a flip chip structure, the rear face of the integrated circuit device 200 may be partially removed with the encapsulant 310 in the planarization process, thereby decreasing the height of the integrated circuit device 200 and thus decreasing the size of the modification 1000A of the semiconductor package.

A recess 301 may be disposed on the upper surface Um of the mold layer 300 that corresponds to the protrusion 510 of the dissipating plate 500. The protrusion 510 of the dissipating plate 500 may be inserted into the recess 301 of the mold layer 300, as will be described in detail below.

The thermal conductive adhesive 400 may be disposed on the upper surfaces Uc and Um of the integrated circuit device 200 and the mold layer 300. The thermal conductive adhesive 400 may spread over a whole surface of the integrated circuit device 200 and the mold layer 300 and may adhere the dissipating plate 500 to the integrated circuit device 200 and the mold layer 300. Thus, the dissipating plate 500 may be sufficiently secured to the integrated circuit device 200 and the mold layer 300 by both the thermal conductive adhesive 400 and the protrusion 510.

The thermal conductive adhesive 400 may include an epoxy resin, a hardening agent and a dissipating agent that are thermal interface materials (TIM). Thus, heat dissipating from the integrated circuit device 200 may be transferred to the dissipating plate 500 through the dissipating agent of the thermal conductive adhesive 400 and then may be dissipated outwards by the dissipating plate 500.

Examples of epoxy resins may include bispenol-A epoxy, bispenol-F epoxy, brominated epoxy, cycloaliyphatic epoxy, etc. These may be used alone or in combinations thereof. An epoxy resin may improve a flame resistance of the semiconductor package 1000 as well as the adherence of the dissipating plate 500 to the integrated circuit device 200 and the mold layer 300.

Examples of hardening agents may include modified cycloaliphatic amine, modified aliphatic amine, aromatic amine, third amines, polyamide, dicyandiamide, etc. These may also be used alone or in combinations thereof A hardening agent may control the durability and hardening speed of the adhesive 400, thereby improving a manufacturing efficiency of the semiconductor package 1000.

The dissipating agent may include thermal interface materials such as thermal conductive fillers that can fill minute grooves and holes between the mold layer 300 and/or the integrated circuit device 200. Examples of the fillers may include calcium carbonate (CaCO3), silica, alumina (Al2O3) powder, etc. These may be used alone or in combinations thereof. Since the dissipating agent includes electrically and thermally conductive materials, heat generated from the integrated circuit device 200 may be transferred to the dissipating plate 500 through the dissipating agent. In particular, when electrically conductive materials are included in the dissipating agent of the thermal conductive adhesive 400 and the thermal conductive adhesive 400 is connected to an external grounding circuit, noise characteristics and electromagnetic interference (EMI) characteristics of the semiconductor package 1000 may be improved by the electrical conductive materials.

The above agents of the thermal conductive adhesive 400 are exemplary and non-limiting, and various other additive agents may be included in the thermal conductive adhesive 400 according to the usage of the semiconductor package 1000 and the packaging characteristics of the semiconductor package 1000. For example, hardening accelerators, flame retardants and tackifiers may be further included in the thermal conductive adhesive 400.

In addition, the thermal conductive adhesive 400 may include a penetration hole 401 that corresponds to the recess 301 of the mold layer 300, so that the protrusion 510 may penetrate the penetration hole 401 and be inserted into the recess 301 of the mold 300.

For example, when the thermal conductive adhesive 400 is formed on the mold layer 300, a laser drill process may be performed on the thermal conductive adhesive 400 and the mold layer 300 to a predetermined depth, so that the penetration hole 401 and the recess 301 may be simultaneously formed in the thermal conductive adhesive 400 and the mold layer 300, respectively. The configurations of the penetration hole 401 and the recess 301 may vary based on the configurations of the protrusion 510 of the dissipating plate 500.

In particular, since the dissipating plate 500 may be primarily secured to the mold layer 300 and/or the integrated circuit device 200 by the protrusion 510, in which case the thermal conductive adhesive 400 may be supplementary for securing the dissipating plate 500, the thermal conductive adhesive 400 may include a relatively low modulus thermal interface material (LMTIM).

When a connector or a securing member is provided in the package, in which case the dissipating member may be adhered to the chip and/or mold layer without an additional securing member, as in the case of a stack package, the thermal conductive adhesive may include a low modulus TIM (LMTIM) having a relatively high thermal conductivity compared with a high modulus TIM (HMTIM). In contrast, when the dissipating member is adhered to the chip and/or the mold layer covering the chip without any other securing members, as in the case of a single chip package, the thermal conductive adhesive uses a high modulus TIM (HMTIM) because the dissipating member is sufficiently secured to the chip and/or the mold layer by the adhesive. Therefore, the dissipating efficiency of a single chip package may deteriorate due to the adhesive. Further, since the thermal conductive adhesive of the stack package includes an HMTIM while the thermal conductive adhesive of the single chip package includes an LMTIM, thermal conductive adhesives that include a TIM may be incompatible with the stack packages and the single chip packages, which may increase the cost and complexity of the packaging process.

However, according to the above exemplary embodiment of the present inventive concept, the protrusion 510 may be used to secure the dissipating plate 500 to the integrated circuit device 200 and the mold layer 300 and thus the thermal conductive adhesive 400 may be supplementary for securing the dissipating plate 500. Therefore, since the thermal conductive adhesive 400 may not need an HMTIM, an LMTIM, which is generally used for stack packages, may be used for the thermal conductive adhesive in a single chip package. That is, the same LMTIM may be used for both the stack package and the single chip package.

The dissipating plate 500 may be disposed on the thermal conductive adhesive 400, so that heat may be dissipated outwards from the integrated circuit device 200 through the dissipating plate 500.

For example, the dissipating plate 500 may cover the upper surface Uc of the integrated circuit device 200 and the upper surface Um of the mold layer 300 and may include the protrusion 510 protruding down from the peripheral portion of the bottom 501 of the dissipating plate 500. The protrusion 510 may be inserted into the mold layer 300 to stably secure the dissipating plate 500 to the mold layer 300. The dissipating plate 500 may make contact with a whole upper surface of the semiconductor package 1000.

The dissipating plate 500 may have various configurations based on the structures and usage of the semiconductor package 1000. For example, the dissipating plate 500 may include a thermal conductive film in contact with the upper surface Uc of the integrated circuit device 200 and an air-cooled or a water-cooled heat exchanger that may be disposed within the integrated circuit device 200. In a present exemplary embodiment, the dissipating plate 500 may include a heat slug in contact with the integrated circuit device 200.

The dissipating plate 500 may have a thermal expansion coefficient and a young's modulus that may be substantially the same those of the silicon substrate of the integrated circuit device 200. In addition, the dissipating plate 500 may have a thermal conductivity that is greater than that of the circuit board 100 and the mold layer 300. Therefore, a warpage of the semiconductor package 1000 caused by the heat from the integrated circuit device 200 may be minimized due to the above physical properties of the dissipating plate 500.

In particular, a central portion of the bottom 501 of the dissipating plate 500 may make contact with the upper surface Uc of the integrated circuit device 200 and the protrusion 510 may protrude from a peripheral portion of the bottom 501 and penetrate the recess 301 of the mold layer 300 via the penetration hole 401 of the adhesive 400. Thus, the dissipating plate 500 may be stably secured to the integrated circuit device 200 and the mold layer 300 by the protrusion 510. The configurations of the protrusion 510 may be variously modified based on the usage and operating conditions of the semiconductor package 1000 and the packaging process.

As shown in FIG. 2A, the protrusion 510 may be continuous along the bottom 501 of the dissipating plate 500 around the integrated circuit device 200 to form a single ring 511 at the peripheral portion of the bottom 501 that encloses the integrated circuit device 200 and that may be inserted into the recess 301 of the mold layer 300. Therefore, the dissipating plate 500 may be sufficiently secured to the integrated circuit device 200 and the mold layer 300 even when no adhesive 400 is interposed between the dissipating plate 500 and the mold layer 300 and the integrated circuit device 200. In such a case, the penetration hole 401 and the recess 301 may also be continuous around a peripheral portion of the mold layer 300 to correspond to the ring-shaped protrusion 511 of the dissipating plate 500. That is, the protrusion 510 and the recess 301 may be continuous along the peripheral portion of the bottom 501 of the dissipating plate 500, and the protrusion 510 may be shaped into the ring 511 that encloses the integrated circuit device 200 in the mold layer 300.

In contrast, as shown in FIGS. 2B and 2C, the protrusion 510 may be discontinuous along the bottom 501 of the dissipating plate 500 and thus may be arranged as separated pieces around the integrated circuit device 200, so that the protrusion 510 includes a plurality of protrusion pieces around the integrated circuit device 200. For example, as shown in FIG. 2B, the dissipating plate 500 may have a square shape and the protrusion 510 may include four L-shaped pieces 512a disposed at the four corners of the square-shaped dissipating plate 500. Alternatively, as shown in FIG. 2C, the protrusion 510 may include four linear pieces 512b around the four corners of the square-shaped dissipating plate 500. That is, the protrusion 510 and the recess 301 may be discontinuous along the peripheral portion of the bottom 501 around the integrated circuit device 200 so that the protrusion 510 includes a plurality of protrusion pieces 512a and 512b symmetric with each other with respect to the integrated circuit device 200.

Each of the L-shaped pieces 512a of the protrusion 510 may include a branch corresponding to the latitudinal line and a branch corresponding longitudinal line of the square-shaped dissipating plate 500. Each of the linear pieces 512b of the protrusion 510 may be diagonally positioned with respect to the latitudinal line and longitudinal line of the square-shaped dissipating plate 500 and thus face each corner of the square-shaped dissipating plate 500. Further, the protrusion pieces 512a and 512b may be located at positions at which warpage caused by thermal expansion differences between the mold layer 300 and the circuit board 100 may be concentrated, so that the protrusion pieces 512a and 512b may prevent warpage of the semiconductor package 1000, to increase the reliability and stability of the semiconductor package 1000.

While present exemplary embodiments disclose a continuous ring-shaped protrusion 511 and discontinuous protrusion pieces 512a and 512b, various modifications are possible based on the packaging processing and operating conditions of the semiconductor package 1000.

The protrusion 510 may be inserted into the recess 301 and may be combined with the mold layer 300 by an interference fit, so that the dissipating plate 500 may be secured to the mold layer 300 by a frictional force. Thus, the protrusion 510 and the recess 301 may be modified as long as there exists an effective frictional force between the protrusion 510 and the mold layer 300 in the recess 301. For example, the protrusion 510 may be modified into a wedge and the recess 301 may be shaped into a groove corresponding to the wedge.

In a modified exemplary embodiment as shown in FIG. 3, the protrusion 510 may be adhered to the inside of the recess 301 and the penetration hole 401 by an additional adhesive 520. The additional adhesive 520 may be coated on a surface of the protrusion 510 and so the protrusion 510 may adhere to inner surfaces of the recess 301 and penetration hole 401. In such a case, the protrusion 510 may be secured to the mold layer 300 by an adhesive force greater than the frictional force of the interference fit.

According to exemplarily embodiments of the present inventive semiconductor package 1000, the dissipating plate 500 may be stably secured to the mold layer 300 by the protrusion 510 while the thermal conductive adhesive 400 supplementally secures the dissipating plate 500 and the mold layer 300, so that the thermal conductive adhesive 400 need not include an HMTIM and an LMTIM may be sufficient for the dissipating agent of the thermal conductive adhesive 400. Therefore, an LMTIM may be included in the thermal conductive adhesive irrespective of the package structure.

In particular, the HMTIM in the thermal conductive adhesive of a conventional single chip package may be replaced with the LMTIM in a semiconductor package 1000, so that the LMTIM may be used as the dissipating agent of the thermal conductive adhesive in both the single chip package and the stack package.

In addition, when the HMTIM in the thermal conductive adhesive of a conventional single chip package is replaced with the LMTIM in a semiconductor package 1000, scratches and dents that may be generated on the top surface of the integrated circuit device 200 in a packaging process may be prevented from transforming into cracks in a subsequent process due to the high modulus of the TIM, thereby reducing packaging defects of the semiconductor package 1000.

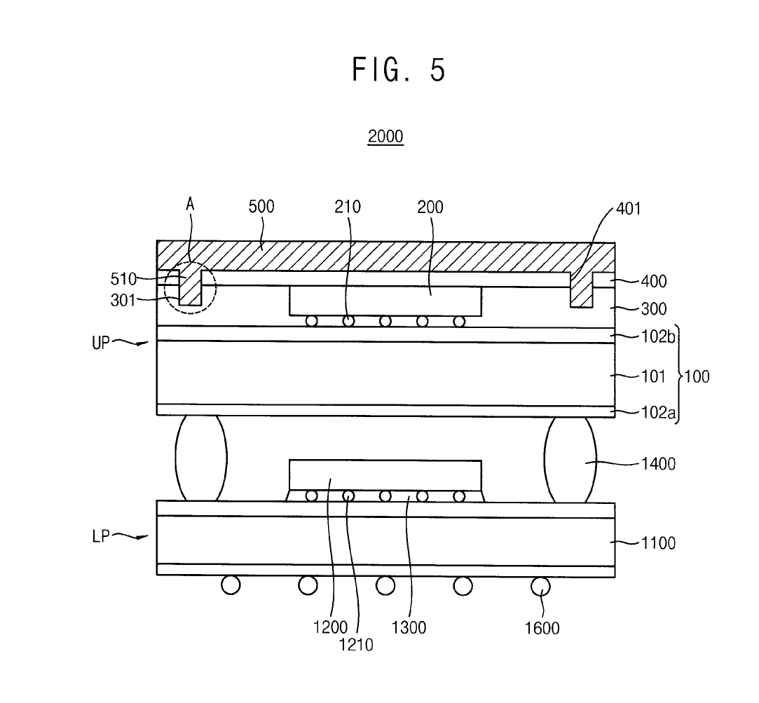

FIG. 5 is a structural view of a stack semiconductor package in accordance with another exemplary embodiment of the present inventive concept.

Referring to FIG. 5, a semiconductor stack package 2000 in accordance with another exemplary embodiment of the present inventive concept may include an upper package UP having a structure substantially the same as the semiconductor package 1000 in FIG. 1, and a lower package LP that may be combined with the upper package UP by an inter-board connector, so that the semiconductor stack package 2000 may have a package-on-package (PoP) structure.

For example, the upper package UP of the semiconductor stack package 2000 may include the circuit board 100, the integrated circuit device 200, the mold layer 300, the dissipating adhesive 400 and the dissipating plate 500, and the lower package LP under the upper package UP may include an additional circuit board 1100 and an additional integrated circuit device 1200. The semiconductor stack package 2000 may further include an inter-board connector 1400 connecting the upper package UP and the lower package LP.

The upper package UP may have substantially the same structure as the semiconductor package 1000 described in detail with reference to FIG. 1, and thus in FIG. 5, the same reference numerals may denote the same elements as in FIG. 1 and detailed descriptions of the same elements will be omitted.

The lower package LP may be individually manufactured independently from the upper package UP, and various circuit boards and semiconductor chips may be included in the lower package LP depending on the characteristics of the semiconductor stack package 2000. For example, the additional circuit board 1100 may include a multilayered printed circuit board (PCB) having a circuit pattern and a plurality of contact pads, similar to the circuit board 100 of the semiconductor package 1000 shown in FIG. 1.

The additional integrated circuit device 1200 may include various semiconductor chips that may be electrically connected to the integrated circuit device 200 and may control an operation of the semiconductor stack package 2000. For example, the additional integrated circuit device 1200 may include a logic chip that controls the upper package UP. In addition, the additional integrated circuit device 1200 may further include various controllers and a plurality of passive devices, so that the lower package LP may be provided as a system-in-package (SIP).

In a present exemplary embodiment, the additional integrated device 1200 may be mounted onto the additional circuit board 1100 as a flip chip structure, and may be electrically and mechanically connected to the additional circuit board 1100 via lower bump structures 1210. The gap space between the additional integrated circuit device 1200 and the additional circuit board 1100 may be filled with an additional under-fill 1300.

While a present exemplary embodiment discloses that the additional integrated circuit device 1200 need not be covered with an encapsulant, an additional mold layer may also be provided to cover the additional integrated circuit device 1200.

Alternatively, the additional integrated circuit device 1200 may have a face-up structure on the additional circuit board 1100 and thus may be electrically connected to the additional circuit board 1100 by bonding wires.

When the additional integrated circuit device 1200 includes a logic chip, which may generate a relatively small amount of heat, the heat from the additional integrated circuit device 1200 may be sufficiently dissipated to surrounding atmosphere through a package gap space between the upper package UP and the lower package LP. In a modified exemplary embodiment, an active air circulator may be further provided with the semiconductor stack package 2000 to actively cool the air in the package gap space.

The upper package UP and the lower package LP may be connected and assembled with each other by the inter-board connector 1400. The inter-board connector 1400 may make contact with the contact pads of the circuit board 100 and the additional circuit board 1100. Thus, the upper package UP and the lower package LP may be secured to each other by the inter-board connector 1400.

For example, the inter-board connector 1400 may include solder balls which may comprise a material selected from the group consisting of tin (Sn), silver (Ag), copper (Cu) and aluminum (Al). In addition, the inter-board connector 1400 may have various shapes, such as a ball, a cylinder, a pillar and a polyhedron.

A plurality of contact terminals 1600 may be disposed on a lower surface of the additional circuit board 1100 and may provide contacts for an external device . For example, the semiconductor stack package 2000 may make contact with a system board of an electronic system via the contact terminal 1600.

While a present exemplary embodiment discloses the integrated circuit device 200 as a single chip package, the integrated circuit device 200 may also be a memory stack package having a plurality of stacked memory chips.

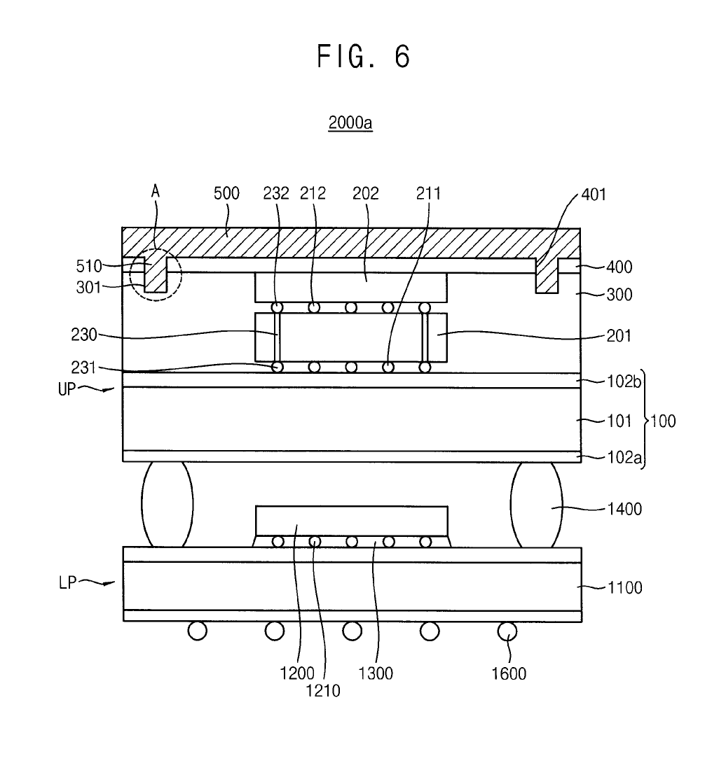

FIG. 6 is a structural view of a modified package of the semiconductor stack package shown in FIG. 5. The modified package in FIG. 6 may have substantially the same structure as the semiconductor stack package 2000 in FIG. 5 except for the integrated circuit package 200. In FIG. 6, the same reference numerals may denote the same elements as in FIG. 5, and thus detailed descriptions of the same elements will be omitted.

Referring to FIG. 6, a modified package 2000a may include a plurality of stacked memory chips on the circuit board 100.

For example, the stacked memory chips may include a first memory chip 201 mounted on the circuit board 100 and a second memory chip 202 stacked on the first memory chip 201. The first memory chip 201 may be secured to the circuit board 100 by a plurality of dummy structures 211 and the second memory chip 202 may be secured to the first memory chip 201 by a plurality of dummy structures 212. The first and the second dummy structures 211 and 212 secure the first and the second memory chips 201 and 202, respectively, and do not bond to the contact pads of the circuit board 100.

The first and the second memory chips 201 and 202 may be connected to the circuit board 100 and/or with each other by a plurality of inter-chip connectors. The first memory chip 201 may be mounted on the circuit board 100 by a flip chip structure and may be connected to the circuit board 100 via a first bump structure 231.

The second memory chip 202 may be connected to the first memory and/or the circuit board 100 through various interconnecting structures. For example, the second memory chip 202 may be stacked on the first memory chip 201 so that the active face may face upwards and a second penetration electrode that penetrates the second memory chip 202 may make contact with a second bump structure 232 on a rear face of the first memory chip 201. A first penetration electrode 230 may penetrate the first memory chip 201 and may make contact with the second bump structure 232, so that the first and the second penetration electrodes may be connected with each other via the second bump structure 232. Therefore, the first and the second memory chips 201 and 202 may be connected with each other by the penetration electrodes and the second bump structure 232, and may be connected to the circuit board 100 via the first bump structure 231.

In contrast, the second memory chip 202 may be stacked on the first memory chip so that the active face may face downwards in a flip chip structure and bonding pads may make contact with the second bump structure 232. In this case, the bonding pads of the second memory chip 202 may be connected to the first penetrating electrode 230 via the second bump 232, and may be connected to the circuit board 100.

The first penetration electrode 230 and the second penetration electrode may include a through-silicon-via (TSV) or a plug type electrode that penetrates the first and the second memory chips 201 and 202, and the first and the second bump structures 231 and 232 may be connected to re-directional lines. The arrangement of the first and the second memory chips 201 and 202 may be modified using the re-directional lines.

Thus, the first and the second memory chips 201 and 202 may be assembled into a single memory stack package and the memory stack package may be bonded to the circuit board 100 via the first bump structures 231. In a present exemplary embodiment, penetration electrodes may be prepared on both sides of the single memory stack package and each of the first and the second memory chips 201 and 202 may function as a single channel, respectively. That is, the single memory stack package may function as a 2-channel memory package.

The first and the second memory chips 201 and 202 may be simultaneously encapsulated by a single MUF process and thus the mold layer 300 may cover both the first and the second memory chips 201 and 202. In an MUF process, liquefied epoxy molding compounds may simultaneously flow into a first gap space between the first memory chip 201 and the circuit board 100, a second gap space between the first memory chip 201 and the second memory chip 202, and a side space between neighboring memory stack packages, so that the first gap space, the second gap space and the side portions of the first and the second memory chips 201 and 202 may be simultaneously filled with the mold layer 300 by a single MUF process.

While a present exemplarily embodiment discloses that the integrated circuit device 200 may include a pair of memory chips in the modified package 2000a, three or more memory chips may also be stacked according to the usage of the modified package 2000.

When a plurality of memory chips are stacked on the circuit board 100 in the modified package 2000a, more heat may be generated from the upper package UP than from the lower package LP with the logic chip. Thus, an upper dissipating member for dissipating heat from the upper package UP may be provided with the upper package UP in addition to a dissipating system for the modified package 2000a. In a present exemplary embodiment, the dissipating plate 500, such as a heat slug, may be provided on the memory stack package and the mold 300 as the upper dissipating member. In this case, the dissipating plate 500 may be stably secured to the mold layer 300 by the protrusion 510, so that the heat generated from the memory stack package may be efficiently dissipated outwards through the dissipating plate 500, so that the modified package 2000a may stably and reliably operate.

In particular, the thermal conductive adhesive 400 may include a low modulus TIM (LMTIM) as a dissipating agent in place of a conventional high modulus TIM (HMTIM). Thus, an LMTIM may be used for manufacturing a modified package 2000a without an HMTIM, which may standardize the packaging process for manufacturing a modified package 2000a.

The additional integrated circuit device 1200 may include various logic chips based on the usage of the stack package 2000 and the modified package 2000a. For example, a logic chip may include micro processors such as a central processing unit (CPU), a controller, or an application specific integrated circuit (ASIC). In addition, a logic chip may include an application processor (AP) chip for a mobile system such as a mobile phone, an MP3 player, a navigation system or a portable multimedia player (PMP) system.

The integrated circuit device 200 may include volatile memory chips such as a dynamic random access memory (DRAM) chip and a static random access memory

(SRAM) chip, and non-volatile memory chips such as flash memory chips. In particular, the memory stack package may include a double data rate (DDR) synchronous dynamic random access memory (SDRAM) chip for the mobile system.

While present exemplarily embodiments disclose that a logic chip may be provided as the additional integrated circuit device 1200 in the stack package 2000 shown in FIG. 5 and the modified package 2000a shown in FIG. 6, other integrated circuit devices may be used as the additional integrated circuit device 1200. Thus, both the integrated circuit device 200 and the additional integrated circuit device 1200 may include memory chips.

According to exemplarily embodiments of the present inventive concept, heat from the heat source of the semiconductor package may be dissipated outwards through the dissipating plate, and the dissipating plate may be stably secured to the mold layer of the semiconductor package. Therefore, the thermal conductive adhesive interposed between the mold layer and the dissipating plate may supplementally secure the dissipating plate and thus the thermal conductive adhesive may include a low modulus TIM (LMTIM) as a dissipating agent instead of a high modulus TIM (HMTIM).

Thus, an LMTIM instead of an HMTIM may be used for manufacturing a semiconductor package for both a single package and a stack package, which may standardize the packaging process for manufacturing a semiconductor package. Further, the dissipating efficiency of the single chip package may be increased by replacing a conventional HMTIM with an LMTIM. Furthermore, scratches and dents that may be generated on a top surface of a single chip package by a packaging process may be prevented from transforming into cracks in a subsequent process due to the high modulus of the TIM, thereby reducing packaging defects of the semiconductor package.

Embodiments of the present inventive concept may be used with high density semiconductor packages that have a dissipating member and to various electronic systems that include a high density semiconductor package, such as a telecommunication system and a storage system. Further, embodiments of the present inventive concept may also be used with dissipating systems of electronic systems having a plurality of integrated circuit devices and which generate a large amount of heat. For example, embodiments of the present inventive concept may also be applied to dissipating systems for micro electro mechanical (MEM) devices, photo-electronic devices and display devices.

The foregoing is illustrative of exemplary embodiments and is not to be construed as limiting thereof. Although a few exemplary embodiments have been described, those skilled in the art will readily appreciate that many modifications are possible in the exemplary embodiments without materially departing from the novel teachings and advantages of the present invention. Accordingly, all such modifications are intended to be included within the scope of the present invention as defined in the claims, and that modifications to the disclosed exemplary embodiments, as well as other exemplary embodiments, are intended to be included within the scope of the appended claims.

What is claimed is:

1. A semiconductor package comprising:
a mold layer that secures an integrated circuit device to a circuit board and that encapsulates the integrated circuit device from its surroundings wherein the integrated circuit device is coplanar with an upper surface of the mold layer and an upper surface of the integrated circuit device is exposed through the mold layer;
a dissipating plate disposed on the integrated circuit device and the mold layer that is configured to dissipate heat from the integrated circuit device, the dissipating plate including at least one protrusion that protrudes from a peripheral portion of a bottom thereof and penetrates into the mold layer; and
a dissipating adhesive configured to adhere the dissipating plate to the mold layer and the integrated circuit device therebetween, the dissipating adhesive configured to transfer heat from the integrated circuit device to the dissipating plate.

2. The semiconductor package of claim 1, wherein the mold layer fills a gap space between the circuit board and the integrated circuit device and side spaces adjacent to the integrated circuit device.

3. The semiconductor package of claim 1, wherein the mold layer includes an under-fill mold in a gap space between the integrated circuit device and the circuit board and an encapsulant that fills side spaces adjacent to the integrated circuit device.

4. The semiconductor package of claim 1, wherein the dissipating plate makes contact with the upper surface of the mold layer and the upper surface of the integrated circuit device, and the mold layer includes at least one recess in the upper surface thereof that corresponds to the protrusion of the dissipating plate.

5. The semiconductor package of claim 4, wherein the protrusion and the recess are continuous along the peripheral portion of the bottom of the dissipating plate, wherein the protrusion has a ring shape that encloses the integrated circuit device in the mold layer.

6. The semiconductor package of claim 4, wherein the protrusion and the recess are discontinuous along the peripheral portion of the bottom of the dissipation plate, wherein the protrusion includes a plurality of protrusion pieces that are symmetric with each other with respect to the integrated circuit device.

7. The semiconductor package of claim 4, further comprising an additional adhesive between the protrusion and an inner surface of the recess.

8. The semiconductor package of claim 1, wherein the dissipating adhesive includes a penetration hole through which the protrusion penetrates and comprises a low modulus thermal interface material (LMTIM).

9. The semiconductor package of claim 1, further comprising:
an additional circuit board under the circuit board;
an additional integrated circuit device on the additional circuit board; and
at least one inter-board connector that connects the circuit board and the additional circuit board, wherein the semiconductor package has a package-on-package (PoP) structure.

10. The semiconductor package of claim 9, wherein the additional integrated circuit device includes a logic chip, and the integrated circuit device includes a plurality of stacked memory chips.

11. The semiconductor package of claim 10, wherein the integrated circuit device and the additional integrated circuit device include a flip chip structure, and the stacked memory chips are connected with each other by a plurality of inter-chip connectors.

12. The semiconductor package of claim 9, wherein the integrated circuit device and the additional integrated circuit device include a plurality of stacked memory chips.

13. A semiconductor package comprising:
a mold layer that secures an integrated circuit device to a circuit board and encapsulates the integrated circuit device from its surroundings and that includes at least one recess in a peripheral portion of an upper surface thereof;
a dissipating plate disposed on an upper surface of the integrated circuit device and an upper surface of the mold layer that is configured to dissipate heat from the integrated circuit device, the dissipating plate including at least one protrusion that protrudes from a peripheral portion of a bottom thereof and penetrates into the recess of the mold layer to combine with the mold layer with an interference fit; and
a dissipating adhesive between the dissipating plate and the mold layer and the integrated circuit device that includes a penetration hole through which the protrusion penetrates and comprises a low modulus thermal interface material (LMTIM) that is configured to transfer heat from the integrated circuit device to the dissipating plate.

14. The semiconductor package of claim 13, wherein an upper surface of the integrated circuit device is coplanar with an upper surface of the mold layer, and an upper surface of the integrated circuit device is exposed through the mold layer, and wherein the mold layer fills a gap space between the circuit board and the integrated circuit device and side spaces adjacent to the integrated circuit device.

15. The semiconductor package of claim 13, wherein an upper surface of the integrated circuit device is coplanar with an upper surface of the mold layer, the mold layer includes an under-fill mold in a gap space between the integrated circuit device and the circuit board and an encapsulant that fills side spaces adjacent to the integrated circuit device, and wherein an upper surface of the integrated circuit device is exposed through the encapsulant.

16. The semiconductor package of claim 13, wherein the protrusion and the recess are continuous along the peripheral portion of the bottom of the dissipating plate, wherein the protrusion has a ring shape that encloses the integrated circuit device in the mold layer.

17. The semiconductor package of claim 13, wherein the protrusion and the recess are discontinuous along the peripheral portion of the bottom of the dissipation plate, wherein the protrusion includes a plurality of protrusion pieces that are symmetric with each other with respect to the integrated circuit device.

18. The semiconductor package of claim 13, further comprising an additional adhesive between the protrusion and an inner surface of the recess.

19. The semiconductor package of claim 13, further comprising:
an additional circuit board under the circuit board;
an additional integrated circuit device on the additional circuit board; and
at least one inter-board connector that connects the circuit board and the additional circuit board, wherein the semiconductor package has a package-on-package (PoP) structure.

20. The semiconductor package of claim 19, wherein the integrated circuit device includes a plurality of stacked memory chips, the integrated circuit device and the additional integrated circuit device include a flip chip structure, and the stacked memory chips are connected with each other by a plurality of inter-chip connectors.
